(19) United States
(12) Patent Application Publication
(10) Pub. No.: US 2024/0097053 A1
(43) Pub. Date: Mar. 21, 2024

(54) SPLICING ADHESIVE FILM, METHOD FOR MANUFACTURING SPLICING ADHESIVE FILM, AND PHOTOVOLTAIC MODULE

(71) Applicants: ZHEJIANG JINKO SOLAR CO., LTD., Haining (CN); JINKO SOLAR CO., LTD., Jiangxi (CN)

(72) Inventors: Hao JIN, Haining (CN); Yunfei XIE, Haining (CN); Zhiqiu GUO, Haining (CN); Yan GAO, Haining (CN); Zixin FAN, Haining (CN)

(21) Appl. No.: 18/179,336

(22) Filed: Mar. 6, 2023

(30) Foreign Application Priority Data
Sep. 16, 2022 (CN) 202211129337.3

(51) Int. Cl. H01L 31/0216; B65H 21/00; B65H 57/14

(52) U.S. Cl. CPC H01L 31/02167; B65H 21/00; B65H 57/14; B65H 2301/51132; B65H 2701/17

(57) ABSTRACT

A splicing adhesive film, a manufacturing method thereof, and a photovoltaic module are provided. The splicing adhesive film includes a first portion and a plurality of second portions. The first portion includes a first material, and each second portion includes a second material. The first portion is located in the central region, and the plurality of second portions each are at least partially located in the edge region. The first portion and each second portion are at least partially overlapped in the first direction. The maximum thickness of each second portion located in the edge region is P, and the maximum thickness of the first portion located in the central region is Q, P>Q.

### CROSS REFERENCE TO RELATED APPLICATIONS

The present application claims the benefit of priority under the Paris Convention to Chinese Patent Application No. 202211129337.3 filed on Sep. 16, 2022, which is incorporated herein by reference in its entirety.

### TECHNICAL FIELD

The disclosure relates in general to the technical field of solar cell modules, and more specifically to a splicing adhesive film, a method for manufacturing the splicing adhesive film, and a photovoltaic module.

### BACKGROUND

With the gradual depletion of non-renewable energy such as fossil fuels, photovoltaic power generation, as way for green and renewable energy production, has attracted more and more attention and development.

Photovoltaic power generation involves converting energy from the sun into electricity using photovoltaic modules. One of a few key materials used in the photovoltaic module is an adhesive film. The adhesive film can be used as an internal packaging material of the photovoltaic module, such as crystalline silicon cells, thin film cells, double glass modules, and double-sided cells, and thus plays a key role in the packaging and protection of the photovoltaic module.

The photovoltaic module in related technologies includes a back plate, an adhesive film, solar cells, an adhesive film, and a front plate that are sequentially stacked. Generally, a sum of an area of each of the solar cells is smaller than an area of each adhesive film, and the two layers of adhesive film are separated at the periphery of corresponding solar cells. During laminating, it is easy to cause damage at the periphery of the corresponding solar cells, resulting in edge fragments and thus making the PV module unusable, thereby reducing the yield of the photovoltaic modules.

Therefore, how to provide a splicing adhesive film, a method for manufacturing the splicing adhesive film, and a photovoltaic module is a technical problem to be solved.

### SUMMARY

In view of the above, a splicing adhesive film, a method for manufacturing the splicing adhesive film, and a photovoltaic module are provided, which can solve the problem that an edge of the photovoltaic module is damaged during laminating.

According to one aspect, a splicing adhesive film is provided. The splicing adhesive film includes a first portion and a plurality of second portions. The first portion includes a first material and is disposed in a central region of the splicing adhesive film. Each of the plurality of second portions includes a second material and is at least partially disposed in an edge region of the splicing adhesive film. The edge region at least partially surrounds the central region. In a first direction: the first portion and each of the plurality of second portions are at least partially overlapped, and a maximum thickness P of each of the plurality of second portions disposed in the edge region is greater than a maximum thickness Q of the first portion disposed in the central region.

According to another aspect, a method for manufacturing a splicing adhesive film including a first portion and a plurality of second portions is provided. The method is implemented by a splicing adhesive film manufacturing apparatus and includes the following. The first portion is formed. The first portion includes a first material and is disposed in a central region of the splicing adhesive film. The plurality of second portions are formed. Each of the plurality of second portions includes a second material and is at least partially disposed in an edge region of the splicing adhesive film, the edge region at least partially surrounding the central region. The first portion and each of the plurality of second portions are at least partially overlapped in a first direction, and a maximum thickness P of each of the plurality of second portions disposed in the edge region is greater than a maximum thickness Q of the first portion disposed in the central region in the first direction. The splicing adhesive film manufacturing apparatus includes a base plate having a first edge with a thickness in a first direction, a roller disposed on a side of the base plate and configured to be controlled to be rotated, a first discharge device, and a plurality of second discharge devices. The first discharge device is disposed on the first edge and configured to be filled with a first material, melt the first material, and discharge a melted first material. The plurality of second discharge devices are disposed on the first edge and configured to be filled with a second material, melt the second material, and discharge a melted second material. The first discharge device is disposed between adjacent second discharge devices in a second direction, and the second direction is perpendicular to the first direction. During rotation of the roller, the melted first material and the melted second material are propagated along a third direction on a surface of the base plate, and the base plate coordinates with the roller to extrude the melted first material to form the first portion and to extrude the melted second material to form the plurality of second portions, wherein the third direction is perpendicular to the second direction. During extrusion of the roller and the base plate, the melted first material and the melted second material are overlapped at a junction of the melted first material and the melted second material, such that the first portion and each of the plurality of second portions are at least partially overlapped in the first direction, and extrusion of the roller and the base plate enables that the maximum thickness P of each of the plurality of second portions formed is greater than the maximum thickness Q of the first portion.

According to yet another aspect, a photovoltaic module is provided. The photovoltaic module includes at least one glass cover plate, at least one splicing adhesive film, and a plurality of solar cells. The at least one glass cover plate includes a first glass cover plate and a second glass cover plate disposed opposite to each other in a first direction. The at least one splicing adhesive film is disposed between the first glass cover plate and the second glass cover plate and includes a first adhesive film and a second adhesive film which are opposite to each other. The plurality of solar cells are disposed between the first adhesive film and the second adhesive film. Each of the at least one splicing adhesive film is a splicing adhesive film according to the above aspect.

### BRIEF DESCRIPTION OF THE DRAWINGS

The accompanying drawings, which are incorporated in and constitute a part of the specification, illustrate embodiments of the disclosure and together with the description thereof, are intended for explaining the principles of the disclosure.

FIG. 1 is a structural schematic view illustrating a splicing adhesive film according to embodiments of the disclosure.

FIG. 2 is a schematic view illustrating a splicing adhesive film manufacturing apparatus for manufacturing the splicing adhesive film according to embodiments of the disclosure.

FIG. 3 is a flow chart illustrating a method for manufacturing a splicing adhesive film by the splicing adhesive film manufacturing apparatus according to embodiments of the disclosure.

FIG. 4 is a schematic plan view illustrating a photovoltaic module according to embodiments of the disclosure.

FIG. 5 is a cross-sectional view illustrating the photovoltaic module in a direction A-A′ of FIG. 4.

The reference numerals in the figures are illustrated as follows: 1—first portion, 2—second portion, 21—first sub-portion, 22—second sub-portion, 3—base plate, 4—first edge, 5—roller, 6—axis, 7—discharge device, 8—first discharge device, 9—second discharge device, 10—first roller, 11—second roller, 12—third roller, 13—first adhesive film, 14—second adhesive film, 15—solar cell, 16—first glass cover plate, 17—second glass cover plate, 100—splicing adhesive film, 200—photovoltaic module, X—first direction, Y—second direction, and Z—third direction.

### DETAILED DESCRIPTION OF THE EMBODIMENTS

Various exemplary embodiments of the disclosure will now be described in detail with reference to the accompanying drawings. It is to be noted that the relative arrangements of components, and the relative order of steps, numeric expressions, and values set forth in these embodiments do not limit the scope of the disclosure unless otherwise specified.

The following description of at least one exemplary embodiment is illustrative only and is not intended to limit the disclosure and application or use of the disclosure.

Techniques, methods, and devices known to those of ordinary skill in the relevant art may not be discussed in detail, but where appropriate, such techniques, methods, and devices should be regarded as part of the specification.

In all examples shown and discussed herein, any specific value should be interpreted as illustrative only and not as a limitation. Therefore, other examples of exemplary embodiments may have different values.

It is to be noted that like numerals and letters denote like terms in the following drawings, and therefore, once an item is defined in one drawing, it does not need to be further discussed in subsequent drawings.

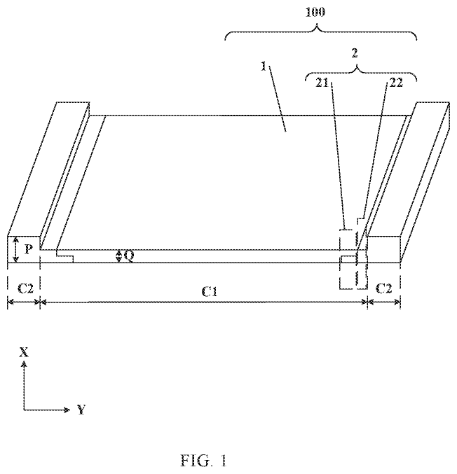

FIG. 1 is a structural schematic view illustrating a splicing adhesive film according to embodiments of the disclosure, which is a specific embodiment of the splicing adhesive film 100 provided in the disclosure. As shown in FIG. 1, the splicing adhesive film 100 has a central region C1 and an edge region C2 at least partially surrounding the central region C1.

The splicing adhesive film 100 includes a first portion 1 and a plurality of second portions 2. The first portion 1 includes a first material, and each second portion 2 includes a second material. The first portion 1 is located in the central region C1, and each of the plurality of second portions 2 is at least partially located in the edge region C2. In a first direction X, the first portion 1 and each of the plurality of second portions 2 are at least partially overlapped. A maximum thickness of each second portion 2 located in the edge region C2 is P, and a maximum thickness of the first portion 1 located in the central region C1 is Q, P>Q.

In FIG. 1, the first portion 1 and each second portion 2 are overlapped in the central region C1, and the plurality of second portions 2 are merely provided on two sides of the first portion 1. It shall be understood that the first portion 1 and each second portion 2 may be overlapped in the edge region C2, and each edge of the first portion 1 is provided with at least one second portion 2, which can be adjusted according to actual needs. In FIG. 1, in an extending direction of each second portion 2, a length of each second portion 2 is equal to a length of the first portion 1. Alternatively, the length of each second portion 2 may be smaller than the length of the first portion 1 in the extending direction of each second portion 2. In addition, each side of two sides of the first portion 1 is provided with at least two second portions 2, and the two second portions 2 are arranged in sequence in the extending direction of each second portion 2. There is a same interval between any two adjacent second portions 2, etc. There is no restriction on the interval between adjacent second portions 2.

It shall be understood that the splicing adhesive film 100 provided in the disclosure has the central region C1 and the edge region C2 at least partially surrounding the central region C1. The splicing adhesive film 100 includes a first portion 1 and a plurality of second portions 2. The first portion 1 includes the first material and each second portion 2 includes the second material. The first portion 1 and the second portion 2 are made from different materials, so that the second portion 2 can adopt a material with better water and oxygen isolation effect than the first portion 1, which can further improve the packaging effect of the adhesive film and avoid excessive cost. The first portion 1 is located in the central region C1, and each of the plurality of second portions 2 is at least partially located in the edge region C2. In the first direction X, the first portion 1 and each second portion 2 are at least partially overlapped, which can ensure better connection effect between the first portion 1 and each second portion 2 and prevent the second portion 2 from falling off. The maximum thickness of each second portion 2 located in the edge region C2 is P, and the maximum thickness of the first portion 1 located in the central region C1 is Q, P>Q. The second portion 2 can protect the edge of the solar cell and play a supporting role at the edge of the solar cell, so as to avoid the edge damage of the photovoltaic module caused by the gap at the edge of the solar cell during the laminating, and improve the quality and production efficiency of the photovoltaic modules.

In some alternative embodiments, with continued reference to FIG. 1, the first material is an ethylene-vinyl acetate copolymer (EVA) and the second material is a polyethylene octene co-elastomer (POE).

It shall be understood that both the EVA and the POE have the characteristics of high light transmission, ultraviolet resistance, and high temperature resistance. The EVA is the most commonly used film material for photovoltaic modules. The POE is better than EVA in water and oxygen isolation. However, the POE is more expensive than the EVA. Therefore, only the second portions located in the edge region C2 being made from the POE can better prevent water and oxygen from penetrating from the edge of the photovoltaic module, and can also avoid high cost of the splicing adhesive film 100.

In some alternative embodiments, with continued reference to FIG. 1, 0.38 mm≤Q≤0.48 mm, Q being the maximum thickness of the first portion 1 located in the central region C1.

It shall be understood that in the first direction X, the maximum thickness of the first portion 1 located in the central region C1 is Q. If Q<0.38 mm, the adhesion ability of the first portion 1 after lamination is relatively weak. If Q>0.48 mm, the light transmittance of the first portion 1 may be affected and the cost may be increased. Therefore, by setting Q to be in a range of greater than or equal to 0.38 mm and less than or equal to 0.48 mm (0.38 mm≤Q≤0.48 mm), the adhesion ability of the first portion 1 after lamination is relatively strong and the light transmittance of the first portion 1 is good.

In some alternative embodiments, with continued reference to FIG. 1, each second portion 2 includes a first sub-portion 21 and a second sub-portion 22 that are located in the central region. The first sub-portion 21 is disposed on a side of the second sub-portion 22 adjacent to the first portion 1.

In the first direction X, the first sub-portion 21 and the first portion 1 are overlapped.

In a second direction Y, a width of the first sub-portion 21 ranges from 1 mm to 20 mm.

It shall be understood that the first sub-portion 21 is an overlapping region between the second portion 2 and the first portion 1. In the second direction Y, the longer the width of the first sub-portion 21, the larger the overlapping region between the second portion 2 and the first portion 1, such that the effect of preventing the second portion 2 from falling off the edge of the first portion 1 is good. However, when the width of the first sub-portion 21 is larger than 20 mm in the second direction Y, the increase in the width of the first sub-portion 21 cannot further prevent the second portion 2 from falling off from the edge of the first portion 1, and may lead to an increase in cost. Therefore, the width of the first sub-portion 21 being in the range of 1 mm to 20 mm in the second direction Y is a preferred range, and the first sub-portion 21 may have a width outside the range of 1 mm to 20 mm. The width of the first sub-portion 21 can be adjusted according to actual situations.

In some alternative embodiments, with continued reference to FIG. 1, taking a cross section in the first direction and the cross section extending in the second direction Y, the first sub-portion 21 is rectangular, right-angled trapezoidal, or right-angled triangular in the cross section.

In other words, in a cross section perpendicular to the extending direction of each second portion 2, the first sub-portion 21 is rectangular, right-angled trapezoidal, or right-angled triangular.

In FIG. 1, the first sub-portion 21 is shown to be rectangular in the cross section. The first sub-portion 21 can also be a right-angled trapezoid, a right-angled triangle, or an irregular shape. Alternatively, mutual interpenetration between the first sub-portion 21 and the first portion 1.

In some embodiments, a method for manufacturing a splicing adhesive film is provided. The splicing adhesive film is implemented by a splicing adhesive film manufacturing apparatus, and the splicing adhesive film manufacturing apparatus includes a base plate, a roller, and a discharge device. The base plate includes a first edge. The roller is disposed on a side of the base plate and includes an axis extending in a second direction. The discharge device, adjacent to the first edge and including a first discharge device and a plurality of second discharge devices, where the plurality of second discharge devices are configured as at least two second discharge devices, where the first discharge device is used for containing a first material and each of the at least two second discharge devices is used for containing a second material. The method includes following operations. The first material and the second material are heated through the first discharge device and the plurality of second discharge devices simultaneously, until the first material and the second material are melted. The roller is rotated about the axis. The first discharge device and the at least t wo second discharge devices discharge simultaneously. The first material is positioned between adjacent second materials, and the first material and the second materials are propagated along a third direction on a surface of the base plate, where the third direction is perpendicular to the second direction. The splicing adhesive film is formed by extruding the first material and the second materials by the base plate and the roller.

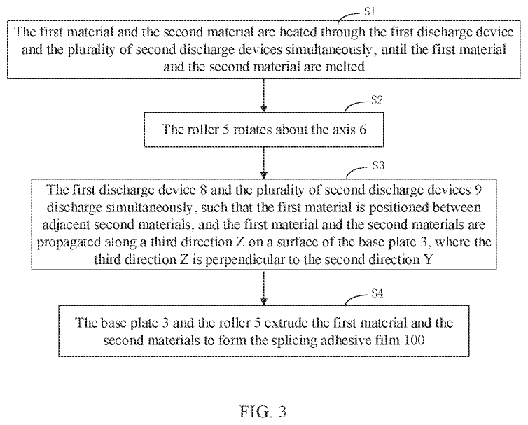

In some alternative embodiments, referring to FIGS. 1, 2, and 3, FIG. 2 is a schematic view illustrating a splicing adhesive film manufacturing apparatus for manufacturing the splicing adhesive film, and FIG. 3 is a flow chart illustrating a method for manufacturing a splicing adhesive film by the splicing adhesive film manufacturing apparatus, which illustrate a specific embodiment of the method for manufacturing the splicing adhesive film 100 provided in the disclosure. The splicing adhesive film 100 provided in the disclosure is manufactured by the splicing adhesive film manufacturing apparatus, and the splicing adhesive film manufacturing apparatus includes a base plate 3, a roller 5, and a discharge device 7.

The base plate 3 includes a first edge 4. The roller 5 is disposed on a side of the base plate 3. The roller 5 includes an axis 6 extending in a second direction Y. The discharge device 7 is adjacent to the first edge 4, and includes a first discharge device 8 and a plurality of second discharge devices 9. There are at least two second discharge devices 9. The first discharge device 8 is used for containing the first material and the second discharge device 9 is used for containing the second material.

The method for manufacturing the splicing adhesive film includes following operations.

At S1, the first material and the second material are heated through the first discharge device and the plurality of second discharge devices simultaneously, until the first material and the second material are melted.

At S2, the roller 5 is rotated about the axis 6.

At S3, the first discharge device 8 and the plurality of second discharge devices 9 discharge simultaneously, such that the first material is positioned between adjacent second materials, and the first material and the second materials are propagated along a third direction Z on a surface of the base plate 3, where the third direction Z is perpendicular to the second direction Y.

At S4, the base plate 3 and the roller 5 extrude the first material and the second materials to form the splicing adhesive film 100.

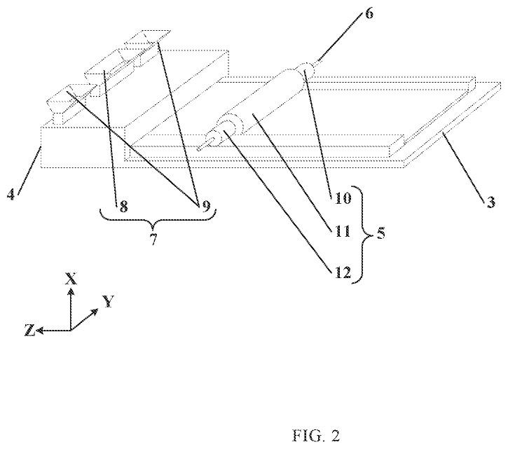

It shall be understood that in FIG. 2, only one first discharge device 8 and two second discharge devices 9 are illustrated. In the disclosure, there may be more than one first discharge device 8 and more than two second discharge devices 9. The roller 5 rotates about the axis 6. A height between the roller 5 and the base plate 3 is not changed, which ensures that a thickness of the splicing adhesive film 100 formed by extrusion of the roller 5 is uniform. The first discharge device 8 and the second discharge devices 9 discharge simultaneously. The first material is located between adjacent second materials. After being extruded by the roller 5 and cooling, the first material forms a first portion 1 and each second material forms a second portion 2. The second portions 2 are located on both sides of the first portion 1. As the roller 5 rotates, the first material and the second material are propagated on the surface of the base plate 3 in a third direction Z, such that the first material and the second materials are transported to the roller 5 for extrusion, to form the splicing adhesive film 100. During the extrusion of the roller 5 and the base plate 3, the first material and the second material are overlapped at a junction of the first material and the second material. The first material and the second material may also penetrate each other at the junction of the first material and the second material, which helps to increase the adhesion between the first portion 1 and the second portions 2 and prevent the second portions 2 from peeling off from the first portion 1.

In some alternative embodiments, with continued reference to FIGS. 1 and 2, the roller 5 includes a first roller 10, a second roller 11, and a third roller 12 connected in sequence in the second direction Y. The first roller 10 has a diameter of M, the third roller 12 has a diameter of N, and the second roller 11 has a diameter of L, L>M=N.

In the second direction Y, a length of the first roller 10 is L1, a length of the third roller 12 is L3, and a discharge width of the second material is L4, L4>L1=L3. In the second direction Y, a length of the second roller 11 is L2, and a discharge width of the first material is L5, L5<L2.

In other words, in the second direction Y, a width of a discharge port of each second discharge device 9 is L4, and a width of a discharge port of the first discharge device 8 is L5.

It shall be understood that the first discharge device 8 corresponds to the second roller 11, and two second discharge devices 9 respectively correspond to the first roller 10 and the third roller 12. The base plate 3 and the roller 5 cooperatively extrude the first material and the second materials to form the splicing adhesive film 100. A side of the base plate 3 close to the roller 5 is a fixed plane, and a thickness of the splicing adhesive film 100 depends on a distance between the roller 5 and the base plate 3. The roller 5 has the axis 6. The first roller 10 has the diameter of M, the third roller 12 has the diameter of N, and the diameter of the second roller 11 is L, where L>M=N, such that a distance between the first roller 10 and the base plate 3 is equal to a distance between the third roller 12 and the base plate 3, and is greater than a distance between the second roller 11 and the base plate 3. The first roller 10 and the third roller 12 extrude the second material with the base plate 3 respectively, and the second roller 11 and the base plate 3 extrude the first material, such that the first portion 1 is formed and the plurality of second portions 2 are respectively formed. Therefore, along the first direction X, the maximum thickness of each second portion 2 is P, and the maximum thickness of the first portion 1 is Q, P>Q, which can protect the edge of the corresponding solar cells and play a supporting role at the edge of the corresponding solar cells, thus avoiding the edge damage of the photovoltaic module caused by the gap at the edge of the solar cell during the laminating. In the second direction Y, the length of the first roller 10 is L1, the length of the third roller 12 is L3, and the discharge width of the second material is L4, where L4>L1=L3. In the second direction Y, the length of the second roller 11 is L2, and the discharge width of the first material is L5, where L5<L2. Since L5<L2, the second material can be extruded into the central region C1 during the extrusion of the roller 5 and the base plate 3, so that the first material and the second material may be overlapped.

In some alternative embodiments, with continued reference to FIG. 2, the first material in the first discharge device 8 may be heated to 80° C. to 90° C., and the second material in the second discharge device 9 may be heated to 95° C. to 100° C.

It shall be understood that since the first material and the second material have different melting point temperatures, the melting of the first material and the second material can be ensured by heating the first material filled in the first discharge device to 80° C. to 90° C. and heating the second material filled in each second discharge device 9 to 95° C. to 100° C.

In some alternative embodiments, with continued reference to FIG. 2, a discharge flow rate of the first discharge device 8 is in a range of 3.5 meter per minute (m/min) to 10 m/min, and a discharge flow rate of each second discharge device 9 is in a range of 3.5 m/min to 10 m/min.

It shall be understood that if the first material is EVA, and the second material is POE, since a friction force of the EVA is greater than that of POE, the EVA is more difficult to discharge than POE. Therefore, to ensure smoothness of the splicing adhesive film 100, a discharge flow rate of the EVA is generally set to be greater than that of the POE. Under the condition that a rotation rate of the roller 5 is determined, if the discharge flow rate of the first material of the first discharge device 8 and the discharge flow rate of the second material of each second discharge device 9 are all less than 3.5 m/min, a discharge amount of the first material and the second material may be too little, which may result in uneven or thin adhesive film formed. If the discharge flow rate of the first material of the first discharge device 8 and the discharge flow rate of the second material of each second discharge device 9 are all greater than 10 m/min, there may be excessive discharge of the first material and the second material, such that the roller 5 cannot effectively extrude the first material and the second material.

Alternatively, if the first material and the second material include same materials, the friction force of the first material is the same as that of the second material, and in this case, to ensure smoothness of the splicing adhesive film 100 and the maximum thickness of each second portion to be greater than the maximum thickness of the first portion, the discharge flow rate of the second material may set to be greater than that of the first material.

In some alternative embodiments, with continued reference to FIG. 2, the rotation rate of the roller 5 ranges from 3.5 rotations per minute (RPM) to 10 RPM.

It shall be understood that when the discharge flow rate of the first material of the first discharge device 8 and the discharge flow rate of the second material of the second discharge device 9 are determined to be in the range of 3.5 m/min to 10 m/min, if the rotation rate of the roller 5 is less than 3.5 RPM, the efficiency of the roller 5 is slow. If the rotation rate of the roller 5 is greater than 10 RPM, the roller 5 cannot effectively extrude the first material and the second material.

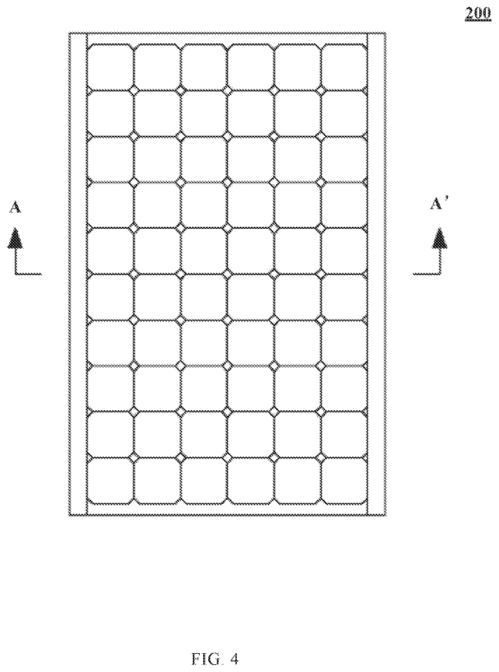

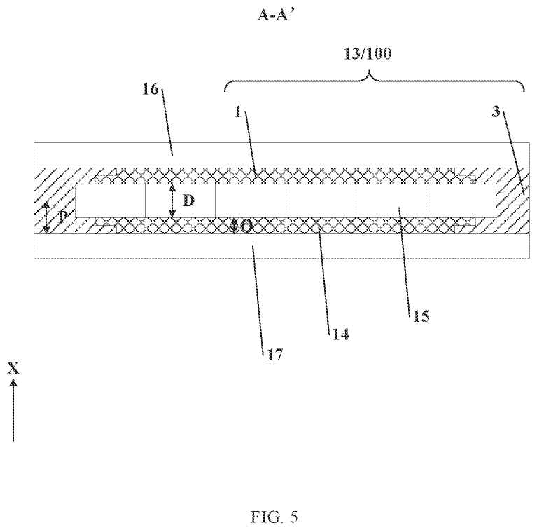

In some alternative embodiments, FIG. 4 is a schematic plan view of a photovoltaic module, and FIG. 5 is a cross-sectional view of the photovoltaic module in direction A-A′ of FIG. 4, which are specific embodiments of the photovoltaic module 200 provided in the disclosure. As illustrated in FIGS. 4 and 5, the photovoltaic module 200 includes a glass cover plate including a first glass cover plate 16 and a second glass cover plate 17 that are disposed opposite to each other in a first direction X.

At least one splicing adhesive film 100 is positioned between the first glass cover plate 16 and the second glass cover plate 17. The at least one splicing adhesive film 100 includes a first adhesive film 13 and a second adhesive film 14 opposite to each other.

It shall be understood that each of the at least one splicing adhesive film 100 is a splicing adhesive film described in any foregoing embodiment, which are not repeated herein.

At least one solar cell 15 is disposed between the first adhesive film 13 and the second adhesive film 14.

FIG. 4 and FIG. 5 only describes the double-glass module as an example of the photovoltaic module 200, including the splicing adhesive film 100 in the above-mentioned embodiment. It shall be understood that the photovoltaic module 200 provided in the embodiment of the disclosure may also be other photovoltaic modules 200 having the splicing adhesive film 100, such as a single-glass module. The photovoltaic module 200 provided in the embodiment of the disclosure has the beneficial effect of the splicing adhesive film 100 provided in embodiments of the disclosure. For details, reference may be made to the specific description of the splicing adhesive film 100 in the above embodiments, which are not be repeated herein.

In some alternative embodiments, with continued reference to FIGS. 4 and 5, the splice adhesive film 100 includes a first adhesive film 13 and a second adhesive film 14 disposed opposite to each other in the first direction X. The at least one solar cell 15 is positioned between the first adhesive film 13 and the second adhesive film 14. The at least one solar cell 15 each have a thickness D along the first direction X, where 0.4D≤P−Q≤0.6D.

Referring to FIGS. 4 and 5, the first adhesive film 13 and the second adhesive film 14 are disposed opposite to each other in the first direction X. The at least one solar cell 15 is positioned between the first adhesive film 13 and the second adhesive film 14. The first glass cover plate 16 is provided on a side of the first adhesive film 13 away from the second adhesive film 14. The second glass cover plate 17 is provided on the side of the second adhesive film 14 away from the first adhesive film 13. After the photovoltaic module 200 is laminated, the first adhesive film 13 and the second adhesive film 14 wrap the at least one solar cell 15, which can effectively isolate water and oxygen. In addition, FIG. 5 schematically illustrates that the first portion 1 and each second portion 2 are overlapped. In an overlapping region between the first portion 1 and each second portion 2, the second portion 2 is located on a side of the first portion 1 away from the solar cell 15 in the first direction X, which can further prevent water and oxygen penetration. In the first direction X, the thickness of each solar cell 15 is D, where 0.4D≤P−Q≤0.6D. If P−Q is less than 0.4 D (P−Q<0.4 D), the second portion 2 of the first adhesive film 13 and the second portion 2 of the second adhesive film 14 has a relatively large spacing, such that the effect of preventing water and oxygen penetration and supporting is poor. If P−Q is greater than 0.6 D (P−Q>0.6 D), a large stress may be generated on the second portion 2 during the laminating. In some embodiments, P−Q=½ D, which can ensure that one side of each of the at least one solar cell 15 is close to the first adhesive film 13 and the other side of each of the at least one solar cell 15 is close to the second adhesive film 14 during laminating of the photovoltaic module 200. In addition, there is no gap between the first adhesive film 13 and the second adhesive film 14 in the edge region C2, so as to avoid edge damage of the photovoltaic module 200 during the laminating.

As can be seen from the above embodiments, the splicing adhesive film provided in the disclosure at least realizes the following beneficial effects.

The splicing adhesive film provided in the disclosure has the central region and the edge region at least partially surrounding the central region. The splicing adhesive film includes the first portion and the plurality of second portions. The first portion includes the first material. Each of the plurality of second portions includes the second material. The first portion is located in the central region. Each of the plurality of second portions is at least partially located in the edge region. In the first direction, the first portion and each second portion are at least partially overlapped. The maximum thickness of each second portion located in the edge region is P, and the maximum thickness of the first portion located in the central region is Q, where P>Q. The first portion and each of the plurality of second portions are made of different materials, so that the second portion can adopt a material with better water and oxygen isolation effect than the first portion, which can further improve the packaging effect of the adhesive film and avoid excessive cost. In the first direction, the first portion and the second portion are at least partially overlapped, which can ensure good connection effect between the first portion and the second portions and avoid falling off of the second portions. The maximum thickness of the second portion located in the edge region is P, and the maximum thickness of the first portion located in the central region is Q, where P>Q, such that the second portion can protect the edge of the corresponding solar cells and play a supporting role at the edge position of the corresponding solar cells, so as to avoid the edge damage of the photovoltaic module caused by the gap at the edge position of the corresponding solar cells during the laminating.

While some particular embodiments of the disclosure have been described in detail by way of example it will be understood by those skilled in the art that the above examples are for illustration only and are not intended to limit the scope of the disclosure. It shall be understood by those skilled in the art that modifications may be made to the above embodiments without departing from the scope and spirit of the disclosure. The scope of the disclosure is defined by the appended claims.

1. A splicing adhesive film, comprising:
a first portion, wherein the first portion includes a first material and is disposed in a central region of the splicing adhesive film; and
a plurality of second portions, wherein each of the plurality of second portions includes a second material and is at least partially disposed in an edge region of the splicing adhesive film, the edge region at least partially surrounding the central region;
wherein the first portion and each of the plurality of second portions partially overlap in a first direction, and a maximum thickness P of each of the plurality of second portions in the edge region is greater than a maximum thickness Q of the first portion in the central region in the first direction;
wherein each of the plurality of second portions includes a first sub-portion and a second sub-portion that are disposed in the central region;
wherein the first sub-portion is disposed on a side of the second sub-portion adjacent to the first portion and overlaps with the first portion, and the second sub-portion does not overlap with the first portion in the first direction; and
wherein the first sub-portion has a width in a range of 1 mm to 20 mm in a second direction perpendicular to the first direction.

2. The splicing adhesive film of claim 1, wherein the first material is an ethylene-vinyl acetate copolymer (EVA) and the second material is a polyethylene octene co-elastomer (POE).

3. The splicing adhesive film of claim 1, wherein the maximum thickness Q of the first portion disposed in the central region is in a range of greater than or equal to 0.38 mm and less than or equal to 0.48 mm.

4. (canceled)

5. The splicing adhesive film of claim 1, wherein the first sub-portion is rectangular, right-angled trapezoidal, or right-angled triangular in a cross section perpendicular to an extending direction of each second portion.

6. The splicing adhesive film of claim 1, wherein a length of each of the plurality of second portions is equal to a length of the first portion in an extending direction of each second portion.

7. A method for manufacturing a splicing adhesive film including a first portion and a plurality of second portions, implemented by a splicing adhesive film manufacturing apparatus, comprising:
forming the first portion, wherein the first portion includes a first material and is disposed in a central region of the splicing adhesive film; and
forming the plurality of second portions, wherein each of the plurality of second portions includes a second material and is at least partially disposed in an edge region of the splicing adhesive film, the edge region at least partially surrounding the central region;
wherein the first portion and each of the plurality of second portions partially overlap in a first direction, and a maximum thickness P of each of the plurality of second portions in the edge region is greater than a maximum thickness Q of the first portion in the central region in the first direction;
wherein each of the plurality of second portions includes a first sub-portion and a second sub-portion that are disposed in the central region;
wherein the first sub-portion is disposed on a side of the second sub-portion adjacent to the first portion and overlaps with the first portion, and the second sub-portion does not overlap with the first portion in the first direction;
wherein the first sub-portion has a width in a range of 1 mm to 20 mm in a second direction perpendicular to the first direction; and
wherein the splicing adhesive film manufacturing apparatus includes:
a base plate having a first edge with a thickness in a first direction;
a roller disposed on a side of the base plate and configured to be controlled to be rotated;
a first discharge device disposed on the first edge and configured to be filled with a first material, melt the first material, and discharge a melted first material; and
a plurality of second discharge devices disposed on the first edge and configured to be filled with a second material, melt the second material, and discharge a melted second material;
wherein, the first discharge device is disposed between adjacent second discharge devices in a second direction, and the second direction is perpendicular to the first direction; and
during rotation of the roller, the melted first material and the melted second material are propagated along a third direction on a surface of the base plate, and the base plate coordinates with the roller to extrude the melted first material to form the first portion and to extrude the melted second material to form the plurality of second portions, wherein the third direction is perpendicular to the second direction; and
during extrusion of the roller and the base plate, the melted first material and the melted second material are overlapped at a junction of the melted first material and the melted second material, such that the first portion and each of the plurality of second portions are at least partially overlapped in the first direction, and extrusion of the roller and the base plate enables that the maximum thickness P of each of the plurality of second portions formed is greater than the maximum thickness Q of the first portion.

8. The method of claim 7, wherein
the roller comprises a first roller, a second roller, and a third roller connected in sequence in the second direction, wherein the first roller has a diameter of M, the third roller has a diameter of N, and the second roller has a diameter of L, where L>M=N, such that a distance between the first roller and the base plate is equal to a distance between the third roller and the base plate and is greater than a distance between the second roller and the base plate, and the maximum thickness P of each of the plurality of second portions formed is greater than the maximum thickness Q of the first portion formed.

9. The method of claim 7, wherein in the second direction, the first roller has a length of L1, the third roller has a length of L3, and a width of a discharge port of each second discharge device is L4, L4>L1=L3, and wherein in the second direction, the second roller has a length of L2, and a width of a discharge port of the first discharge device is L5, wherein L5<L2, such that during extrusion of the roller and the base plate, the second material is extruded into the central region and the first material and the second material are overlapped.

10. The method of claim 7, wherein forming the first portion and the plurality of second portions includes heating, through the first discharge device and the plurality of second discharge devices simultaneously, the first material and the second material until the first material and the second material are melted, wherein the first material filled in the first discharge device is heated to 80° C. to 90° C., and the second material filled in each second discharge device is heated to 95° C. to 100° C.

11. The method of claim 7, wherein a discharge flow rate of the first material of the first discharge device is in a range of 3.5 m/min to 10 m/min, and a discharge flow rate of the second material of each second discharge device is in a range of 3.5 m/min to 10 m/min.

12. The method of claim 7, wherein a rotation rate of the roller ranges from 3.5 rotations per minute (RPM) to 10 RPM.

13. The method of claim 7, wherein the first material is an ethylene-vinyl acetate copolymer (EVA) and the second material is a polyethylene octene co-elastomer (POE).

14. A photovoltaic module, comprising:
at least one glass cover plate, comprising a first glass cover plate and a second glass cover plate that are disposed opposite to each other in a first direction;
at least one splicing adhesive film disposed between the first glass cover plate and the second glass cover plate and comprising a first adhesive film and a second adhesive film which are opposite to each other; and
a plurality of solar cells disposed between the first adhesive film and the second adhesive film, wherein
each of the at least one splicing adhesive film includes:
a first portion, wherein the first portion includes a first material and is disposed in a central region of the splicing adhesive film; and
a plurality of second portions, wherein each of the plurality of second portions includes a second material and is at least partially disposed in an edge region of the splicing adhesive film, and the edge region is at least partially surrounding the central region;
wherein the first portion and each of the plurality of second portions partially overlap in a first direction, and a maximum thickness P of each of the plurality of second portions in the edge region is greater than a maximum thickness Q of the first portion in the central region in the first direction;
wherein each of the plurality of second portions includes a first sub-portion and a second sub-portion that are disposed in the central region;
wherein the first sub-portion is disposed on a side of the second sub-portion adjacent to the first portion and overlaps with the first portion, and the second sub-portion does not overlap with the first portion in the first direction and overlaps with at least one solar cell of the plurality of solar cells in the first direction; and
wherein the first sub-portion has a width in a range of 1 mm to 20 mm in a second direction perpendicular to the first direction.

15. The photovoltaic module of claim 14, wherein in the first direction, each of the plurality of solar cells has a thickness of D, wherein 0.4D≤P−Q≤0.6D.

16. The photovoltaic module of claim 14, wherein the first material is an ethylene-vinyl acetate copolymer (EVA) and the second material is a polyethylene octene co-elastomer (POE).

17. The photovoltaic module of claim 14, wherein the maximum thickness Q of the first portion disposed in the central region is in a range of greater than or equal to 0.38 mm and less than or equal to 0.48 mm.

18. (canceled)

19. The photovoltaic module of claim 14, wherein the first sub-portion is rectangular, right-angled trapezoidal, or right-angled triangular in a cross section perpendicular to an extending direction of each second portion.

20. The photovoltaic module of claim 14, wherein a length of each of the plurality of second portions is equal to a length of the first portion in an extending direction of each second portion.

21. The splicing adhesive film of claim 1, wherein the plurality of second portions include at least two second portions arranged on opposite sides of the first portion, each of the at least two second portions extends in a same direction, and any two adjacent second portions of the plurality of second portions are spaced apart from each other by a same interval.

22. The splicing adhesive film of claim 1, wherein the second sub-portion has a thickness of Q in the first direction.
